(19) United States
(12) Patent Application Publication
(10) Pub. No.: US 2023/0083158 A1
(43) Pub. Date: Mar. 16, 2023

(54) SEMICONDUCTOR DEVICE

(71) Applicant: Kioxia Corporation, Tokyo (JP)

(72) Inventors: Kenichi MATOBA, Yokohama (JP); Takahiro TSURUDO, Yokohama (JP); Yoshiaki TAKAHASHI, Yokohama (JP); Yoichi MIZUTA, Yokohama (JP); Yoshifumi SHIMAMURA, Yokohama (JP); Toru OZAWA, Kamakura (JP); Takumi KOSAKI, Kamakura (JP); Kouji NAKAO, Yokohama (JP)

(73) Assignee: Kioxia Corporation, Tokyo (JP)

(21) Appl. No.: 17/682,889

(22) Filed: Feb. 28, 2022

(30) Foreign Application Priority Data
Sep. 15, 2021 (JP) 2021-150513

(51) Int. Cl. H01L 27/11529; H01L 27/108

(52) U.S. Cl. CPC H01L 27/11529; H01L 27/10811

(57) ABSTRACT

A semiconductor device includes an active region, and an edge seal formed on at least a portion of an outer edge of the active region. The edge seal includes a first stacked body having a first conductive layer, and a second stacked body having a second conductive layer. The first conductive layer is coupled to a first voltage, the second conductive layer is coupled to a second voltage different from the first voltage, and the first conductive layer faces the second conductive layer.

### CROSS-REFERENCE TO RELATED APPLICATION(S)

This application is based upon and claims the benefit of priority from Japanese Patent Application No. 2021-150513, filed Sep. 15, 2021, the entire contents of which are incorporated herein by reference.

### FIELD

Embodiments described herein relate generally to a semiconductor device.

### BACKGROUND

A semiconductor device may have a capacitive element. The semiconductor device is generally desired to have a reduced chip size.

### DESCRIPTION OF THE DRAWINGS

FIG. 1 is a top view of a semiconductor chip of a semiconductor device of an embodiment.

FIG. 2 is a block diagram illustrating a configuration of a memory system in which the semiconductor chip of the embodiment is used.

FIG. 3 is a schematic circuit diagram illustrating a configuration of a part of an input/output control circuit of the semiconductor chip related to the embodiment.

FIG. 4 is a cross-sectional view of a part of an area of a semiconductor memory device of the embodiment.

FIG. 5 is a schematic view of an edge seal of the embodiment.

FIG. 6 is a schematic view of an edge seal, which is orthogonal to the surface of the semiconductor chip as a comparative example.

FIG. 7 is a plan view illustrating shapes and arrangement of two adjacent conductive layers related to Modification 1 of the embodiment.

FIG. 8 is a plan view illustrating shapes and arrangement of each of two conductive layers in one wiring layer and each of two conductive layers in another wiring layer, in relation to Modification 2 of the embodiment.

FIG. 9 is a schematic view illustrating a capacitance between two wiring layers in relation to Modification 2 of the embodiment.

FIG. 10 is a plan view illustrating shapes and arrangement of two conductive layers in one wiring layer in relation to Modification 3 of the embodiment.

FIG. 11 is a plan view illustrating shapes and arrangement of two conductive layers in one wiring layer and two conductive layers in another wiring layer, in relation to Modification 4 of the embodiment.

FIG. 12 is a schematic cross-sectional view illustrating a configuration of a semiconductor chip of Modification 5 of the embodiment.

FIG. 13 is a schematic view of a NAND-type flash memory having two semiconductor chips bonded to each other, in relation to Modification 5 of the embodiment.

FIG. 14 is a schematic view of a NAND-type flash memory having two semiconductor chips bonded to each other, in relation to another example of Modification 5 of the embodiment.

FIG. 15 is a block diagram of a semiconductor device of Modification 6 of the embodiment.

### DETAILED DESCRIPTION

Embodiments provide a semiconductor device whose chip size may be reduced.

In general, according to one embodiment, a semiconductor device includes an active region, and an edge seal formed on at least a portion of an outer edge of the active region. The edge seal includes a first stacked body having a first conductive layer, and a second stacked body having a second conductive layer. The first conductive layer is coupled to a first voltage, the second conductive layer is coupled to a second voltage different from the first voltage, and the first conductive layer faces the second conductive layer.

Hereinafter, an embodiment will be described with reference to drawings.

### Configuration

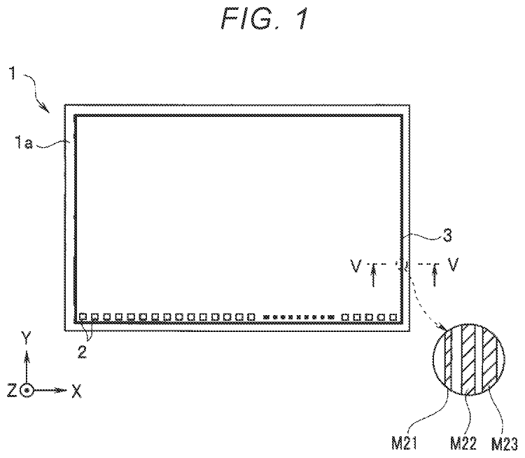

FIG. 1 is a top view of a semiconductor chip 1 of a semiconductor device of the present embodiment. Here, the semiconductor chip 1 is a NAND-type flash memory. A non-volatile NAND-type flash memory is a non-volatile memory used for a memory system. Various circuits and a memory cell array for the NAND-type flash memory are formed on the semiconductor chip 1. Further, a plurality of external pads 2 for electrical connection with the outside is provided. Here, the external pads 2 are arranged along one side of the rectangular semiconductor chip 1.

Further, as illustrated in FIG. 1, an edge seal 3 is formed on the semiconductor chip 1 so as to surround an element forming region (or active region) having various circuits and the memory cell array, or the plurality of external pads 2. The edge seal 3 has a role of stopping cracks generated when the individualized semiconductor chip 1 is cut out through dicing-cut of a semiconductor wafer, or the edge seal 3 has a role of preventing contaminants such as impurity ions from invading from the outside. Here, the edge seal 3 surrounds the entire periphery of the various circuits and the memory cell array in the XY directions, but may be formed only in a part thereof.

Hereinafter, a stacking direction of a memory cell array 23 and peripheral circuits to be described later is set as a Z direction. One direction that intersects the Z direction, for example, a direction orthogonal to the Z direction, is set as a Y direction. One direction that intersects each of the Z and Y directions, for example, a direction orthogonal to each of the Z and Y directions, is set as an X direction.

As described later, the configuration of the edge seal 3 includes a plurality of conductive layers, and a plurality of contacts electrically connecting the conductive layers.

In the present embodiment, as indicated by the dotted line arrow in FIG. 1, the edge seal 3 has three conductive layers M21, M22, and M23 (indicated by diagonal lines) in an uppermost wiring layer M2.

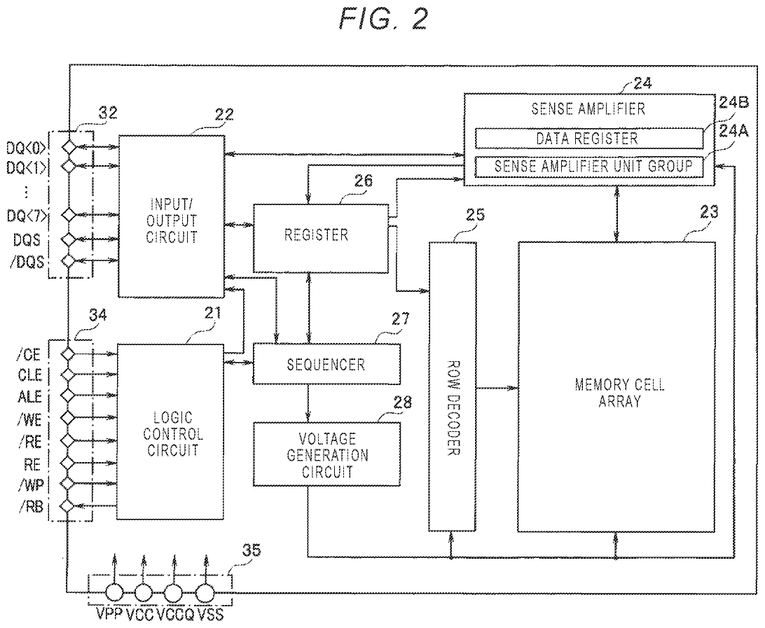

FIG. 2 is a block diagram illustrating an example of a configuration of the semiconductor device of the present embodiment. The semiconductor device includes a logic control circuit 21, an input/output circuit 22, the memory cell array 23, a sense amplifier 24, a row decoder 25, a register 26, a sequencer 27, a voltage generation circuit 28, an input/output pad group 32, a logic control pad group 34, and a power input control group 35.

The memory cell array 23 includes a plurality of blocks. Each of the blocks includes a plurality of memory cell transistors (memory cells). In order to control voltages to be applied to the memory cell transistors, a plurality of bit lines, a plurality of word lines, a source line and others are arranged in the memory cell array 23.

The input/output pad group 32 transmits/receives each signal including data to/from a memory controller (not illustrated), and thus, includes a plurality of terminals (pads) corresponding to signals DQ<7:0>, and data strobe signals DQS and /DQS.

The logic control pad group 34 transmits/receives each signal to/from the memory controller, and thus, includes a plurality of terminals (pads) corresponding to a chip enable signal /CE, a command latch enable signal CLE, an address latch enable signal ALE, a write enable signal /WE, read enable signals RE and /RE, and a write protect signal /WP.

The power input control group 35 supplies various operating power sources from the outside to the semiconductor chip 1, and thus, includes a plurality of terminals to which power supply voltages VCC, VCCQ, and VPP, and a ground voltage VSS are input. The power supply voltage VCC is a circuit power supply voltage that is generally given as an operating power source from the outside, and, for example, a voltage of about 3.3 V is input. As for the power supply voltage VCCQ, for example, a voltage of 1.2 V is input. The power supply voltage VCCQ is used when signals are transmitted/received between the memory controller and the semiconductor chip 1.

The power supply voltage VPP is a power supply voltage higher than the power supply voltage VCC, and, for example, a voltage of 12 V is input. When data is written into the memory cell array 23, or data is erased, a high voltage of about 20 V is required. Here, it is possible to generate a desired voltage at a high speed with low power consumption by boosting the power supply voltage VPP of about 12 V rather than boosting the power supply voltage Vcc of about 3.3 V, by a boosting circuit of the voltage generation circuit 28. The power supply voltage VCC is a power source supplied, as a standard, to the semiconductor chip 1, and the power supply voltage VPP is, for example, a power source additionally and optionally supplied according to the usage environment.

The logic control circuit 21 and the input/output circuit 22 are connected to the memory controller via a NAND bus. The input/output circuit 22 transmits/receives signals DQ (e.g., DQ0 to DQ7) to/from the memory controller via the NAND bus.

The logic control circuit 21 receives external control signals (e.g., a chip enable signal /CE, a command latch enable signal CLE, an address latch enable signal ALE, a write enable signal /WE, read enable signals RE and /RE, and a write protect signal /WP) from the memory controller via the NAND bus. The logic control circuit 21 transmits a ready/busy signal /RB to the memory controller via the NAND bus.

The input/output circuit 22 transmits/receives signals DQ<7:0>, and data strobe signals DQS and /DQS to/from the memory controller. The input/output circuit 22 transmits a command and an address within the signals DQ<7:0>to the register 26. Further, the input/output circuit 22 transmits/receives write data, and read data to/from the sense amplifier 24.

The register 26 includes a command register, an address register, a status register and others. The command register temporarily stores a command. The address register temporarily stores an address. The status register temporarily stores data required for operating the semiconductor chip 1. The register 26 is configured with, for example, a SRAM.

The sequencer 27 as a controller receives a command from the register 26, and controls the semiconductor chip 1 according to a sequence based on the command.

The voltage generation circuit 28 receives a power supply voltage from the outside of the semiconductor chip 1, and uses the power supply voltage to generate a plurality of voltages required for a write operation, a read operation, and an erase operation. The voltage generation circuit 28 supplies the generated voltages to the memory cell array 23, the sense amplifier 24, the row decoder 25 and others.

The row decoder 25 receives a row address from the register 26, and decodes the row address. The row decoder 25 performs a word line selecting operation based on the decoded row address. Then, the row decoder 25 transmits a plurality of voltages required for a write operation, a read operation, and an erase operation to the selected block.

The sense amplifier 24 receives a column address from the register 26, and decodes the column address. The sense amplifier 24 includes a sense amplifier unit group 24A, and a data register 24B. The sense amplifier unit group 24A is connected to each bit line, and selects any of bit lines based on the decoded column address. During a data reading, the sense amplifier unit group 24A detects and amplifies data read from the memory cell transistor to the bit line. During a data writing, the sense amplifier unit group 24A transmits write data to the bit line.

During a data reading, the data register 24B temporarily stores data detected by the sense amplifier unit group 24A, and serially transmits this to the input/output circuit 22. During a data writing, the data register 24B temporarily stores data serially transmitted from the input/output circuit 22, and transmits the data to the sense amplifier unit group 24A. The data register 24B is configured with a SRAM or the like.

The plurality of external pads 2 illustrated in FIG. 1 includes a plurality of pads for receiving signals corresponding to various signals of the NAND bus, a pad to which a power supply voltage VCC is supplied, and a pad to which a ground voltage VSS is applied.

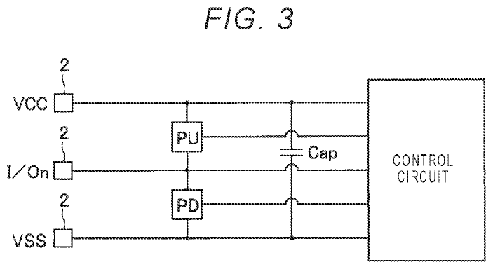

FIG. 3 is a schematic circuit diagram illustrating a configuration of a part of an input/output control circuit I/O of the semiconductor chip 1.

As described above, some of the external pads 2 function as a power supply terminal and a data input/output terminal I/On (n is a natural number of 0 to 7). The two pads for the power supply voltage VCC and the ground voltage VSS are connected to circuits, respectively, in the input/output control circuit I/O to supply a power.

The input/output control circuit I/O includes a control circuit, a pull-up circuit PU, and a pull-down circuit PD. The input/output control circuit I/O includes a data output control circuit that outputs a signal from the data input/output terminal I/On when data is output, and a data input control circuit that inputs a signal from the data input/output terminal I/On when data is input.

The data output control circuit includes a pull-up circuit PU connected between the external pad 2 for the power supply voltage VCC and the external pad 2 for the data input/output I/On, and a pull-down circuit PD connected between the external pad 2 for the ground voltage VSS and the external pad 2 for the data input/output I/On.

The pull-up circuit PU includes K (K is a natural number) PMOS transistors connected in parallel between the external pad 2 for the power supply voltage VCC and the external pad 2 for the data input/output I/On. Gate electrodes of the PMOS transistors are connected to K output terminals of a pull-up driver circuit in the control circuit, respectively. The pull-down circuit PD includes L (L is a natural number) NMOS transistors connected in parallel between the external pad 2 for the ground voltage VSS and the external pad 2 for the data input/output I/On. Gate electrodes of these NMOS transistors are connected to L output terminals of a pull-down driver circuit in the control circuit, respectively. When data is output, according to the output data, the pull-up circuit PU or the pull-down circuit PD is selectively driven. Due to the selective driving, the external pad 2 for the data input/output I/On is in electrical conduction with the external pad 2 for the power supply voltage VCC or the external pad 2 for the ground voltage VSS. Here, the output impedance is controlled according to the number of PMOS transistors or NMOS transistors that are turned ON during driving.

The data input control circuit has a comparator in the control circuit. One input terminal of the comparator is connected to the external pad 2 for the data input/output I/On, and the other input terminal is connected to a reference voltage supply line. When data is input, for example, if the voltage of the external pad 2 for the data input/output I/On is larger than a reference voltage, “H” is output from the comparator. For example, if the voltage of the external pad 2 for the data input/output I/On is smaller than a reference voltage, “L” is output from the comparator.

An inter-power source capacitive element Cap is connected between the external pad 2 for the power supply voltage VCC and the external pad 2 for the ground voltage VSS. The inter-power source capacitive element Cap has an inter-power source capacity for stabilizing, a power supply voltage which is a voltage between the external pad 2 for the power supply voltage VCC and the external pad 2 for the ground voltage VSS, even during a high-speed operation.

In general, when electric charges are charged or discharged in various elements, a fluctuation occurs in the power supply voltage. Here, by providing the inter-power source capacitive element between the power supply voltage terminal and the ground voltage terminal, it is possible to prevent the fluctuation of the power supply voltage.

Further, in the same manner that there is an inter-power source capacity between the power supply voltage VCC and the ground voltage VSS as illustrated in FIG. 3, there is an inter-power source capacity between the power supply voltage VPP and the ground voltage VSS or between the power supply voltage VCCQ and the ground voltage VSS.

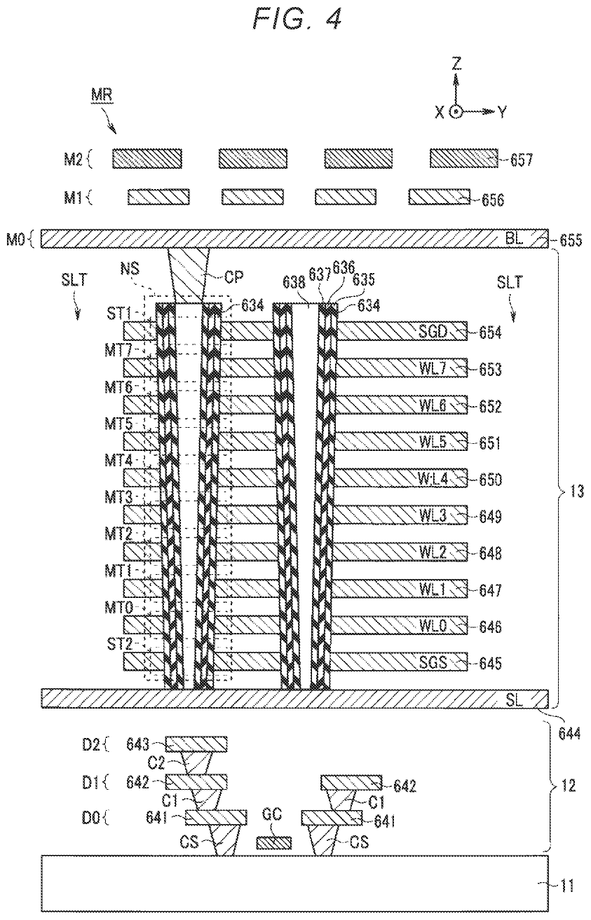

Here, descriptions will be made on an example of a configuration of the semiconductor chip 1 having a non-volatile memory. FIG. 4 is a cross-sectional view of a part of an area of a semiconductor memory device that has a peripheral circuit region, and a memory cell array region 13 in which the memory cell array 23 of a NAND memory having a three-dimensional structure is formed in the layer above the peripheral circuit region. FIG. 4 illustrates a semiconductor memory device having a CMOS UNDER ARRAY (CUA) structure.

As illustrated in FIG. 4, in the memory region, the semiconductor chip 1 includes a semiconductor substrate 11, conductors 641 to 657, a memory hole 634, and contact plugs CS, C1, C2, and CP. Further, the drawings to be described herein below omit the illustration of each of a p-type or n-type well region formed in the upper surface portion of the semiconductor substrate 11, an impurity diffusion region formed in each well region, and an element separation region that insulates well regions from each other.

In the memory region, for example, a plurality of contacts CS is formed on the semiconductor substrate 11. The contacts CS are connected to impurity diffusion regions (active regions AA) formed in the semiconductor substrate 11. The memory cell array 23 of the NAND memory is disposed on the semiconductor substrate 11 via a peripheral circuit region 12. Peripheral circuits such as an input/output circuit are also formed in the peripheral circuit region 12.

The conductor 641 that forms a wiring pattern is provided on each contact CS. A part of a plurality of wiring patterns of the conductors 641 is a part of the bit lines described above. Another part of the plurality of wiring patterns is a part of wirings of various transistors. In this case, a gate electrode GC is provided near the region between the adjacent conductors 641. In this case, one of the adjacent conductors 641 is connected to a drain of a transistor, and the other conductor is connected to a source of the transistor.

For example, the contact C1 is formed on each conductor 641. For example, the conductor 642 is provided on each contact C1. For example, the contact C2 is formed on the conductor 642. For example, the conductor 643 is provided on the contact C2.

The wiring pattern of each of the conductors 641, 642, and 643 is disposed in the peripheral circuit region 12 between a sense amplifier circuit (not illustrated) and the memory cell array. Further, here, three wiring layers are formed in the peripheral circuit region 12. Alternatively, in the peripheral circuit region 12, two or less wiring layers, or four or more wiring layers may be formed.

For example, the conductor 644 is provided above the conductor 643 via an interlayer insulating film. The conductor 644 is, for example, a source line SL formed in a plate shape parallel to the XY plane. Above the conductor 644, for example, the conductors 645 to 654 are stacked in this order while corresponding to each string unit SU. Between conductors adjacent to each other in the Z direction among these conductors, an interlayer insulating film (not illustrated) is formed.

The structure corresponding to one string unit SU is provided between adjacent slits SLT. The slit SLT extends in, for example, the X direction and the Z direction, and insulates the conductors 645 to 654 provided in adjacent string units SU (not illustrated) from each other.

Each of the conductors 645 to 654 is formed in, for example, a plate shape parallel to the XY plane. For example, the conductor 645 corresponds to a select gate line SGS, the conductors 646 to 653 correspond to word lines WL0 to WL7, respectively, and the conductor 654 corresponds to a select gate line SGD.

Each memory hole 634 is formed in a columnar shape extending through each of the conductors 645 to 654, and is in contact with the conductor 644. In the memory hole 634, for example, a block insulating film 635, a charge storage film 636, and a gate insulating film 637 are sequentially formed, and further, a semiconductor column 638 is embedded in the memory hole 634.

For example, a portion where the memory hole 634 and the conductor 645 intersect functions as a select transistor ST2. A portion where the memory hole 634 and each of the conductors 645 to 654 intersect functions as a memory cell transistor MT (memory cell). A portion where the memory hole 634 and the conductor 654 intersect function as a select transistor ST1.

The conductor 655 is provided in the layer above an upper surface of the memory hole 634 via an interlayer insulating film. The conductor 655 is formed in a line shape extending in the Y direction, and corresponds to the bit line BL. The conductors 655 are arranged at intervals in the X direction (not illustrated). In each string unit SU, the conductor 655 is electrically connected to the semiconductor column 638 in one corresponding memory hole 634.

Specifically, in each string unit SU, for example, a contact plug CP is provided on the semiconductor column 638 in each memory hole 634, and one conductor 655 is provided on the contact plug CP. Further, the present disclosure is not limited to this configuration, and the semiconductor column 638 in the memory hole 634 may be connected to the conductor 655 via a plurality of contacts, wirings or the like.

The conductor 656 is provided in the layer above the layer where the conductor 655 is provided, via an interlayer insulating film. The conductor 657 is provided in the layer above the layer where the conductor 656 is provided, via an interlayer insulating film.

The conductors 656 and 657 correspond to, for example, wirings for connecting wirings provided in the memory cell array 23 to the peripheral circuits formed under the memory cell array 23. The conductors 656 and 657 may be connected to each other by a columnar contact (not illustrated).

### Configuration of Edge Seal

Next, the configuration of the edge seal 3 will be described.

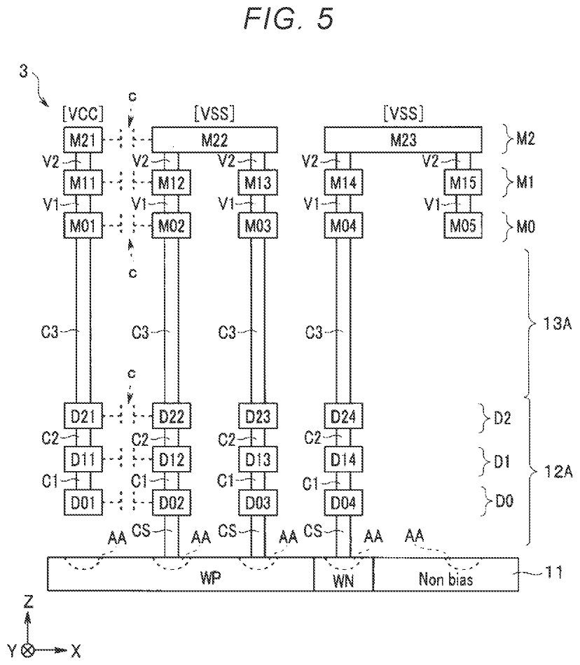

FIG. 5 is a schematic view of the edge seal 3. FIG. 5 illustrates a cross section taken along the V-V line of FIG. 1. That is, FIG. 5 illustrates a cross section of the edge seal 3, which is orthogonal to a direction where the plurality of conductive layers extends in the edge seal 3.

The semiconductor substrate 11 of the semiconductor chip 1 has a p-type well region WP, a n-type well region WN, and a non-bias region NB (Non bias). The p-type well region WP and the n-type well region WN have a n+type diffusion layer and a P+type diffusion layer as active regions AA, respectively.

The edge seal 3 includes a plurality of wiring layers D0, D1, and D2. The wiring layer D0 includes a plurality of (four in FIG. 5) conductive layers D01, D02, D03, and D04. The wiring layer D1 includes a plurality of (four in FIG. 5) conductive layers D11, D12, D13, and D14. The wiring layer D2 includes a plurality of (four in FIG. 5) conductive layers D21, D22, D23, and D24.

When viewed in a direction orthogonal to a surface 1a, the conductive layers D01, D02, D03, and D04 are formed in the order of the conductive layers D01, D02, D03, and D04 from the inside of the surface la toward the outer edge.

When viewed in a direction orthogonal to the surface 1a, the conductive layers D11, D12, D13, and D14 are formed in the order of the conductive layers D11, D12, D13, and D14 from the inside of the surface la toward the outer edge.

When viewed in a direction orthogonal to the surface 1a, the conductive layers D21, D22, D23, and D24 are formed in the order of the conductive layers D21, D22, D23, and D24 from the inside of the surface 1a toward the outer edge.

As illustrated in FIG. 5, the conductive layers D02, D03, and D04 in the wiring layer DO are electrically connected to three active regions AA by contact plugs CS, respectively. Further, as illustrated in FIG. 5, the conductive layer D01 is not electrically connected to an active region AA.

The conductive layers D01, D02, D03, and D04 in the wiring layer D0 are electrically connected to the conductive layers D11, D12, D13, and D14 in the wiring layer D1 by contact plugs C1, respectively. The conductive layers D11, D12, D13, and D14 in the wiring layer D1 are electrically connected to the conductive layers D21, D22, D23, and D24 in the wiring layer D2 by contact plugs C2, respectively.

The edge seal 3 has wiring layers M0, M1, and M2 above the peripheral circuit region 12. The wiring layer M0 includes a plurality of (five in FIG. 5) conductive layers M01, M02, M03, M04, and M05. The wiring layer M1 includes a plurality of (five in FIG. 5) conductive layers M11, M12, M13, M14, and M15. The wiring layer M2 includes a plurality of (three in FIG. 5) conductive layers M21, M22, and M23.

When viewed in a direction orthogonal to the surface la, the conductive layers M01, M02, M03, M04, and M05 are formed in the order of the conductive layers M01, M02, M03, M04, and M05 from the inside of the surface 1a toward the outer edge.

When viewed in a direction orthogonal to the surface 1a, the conductive layers M11, M12, M13, M14, and M15 are formed in the order of the conductive layers M11, M12, M13, M14, and M15 from the inside of the surface 1a toward the outer edge.

When viewed in a direction orthogonal to the surface 1a, the conductive layers M21, M22, and M23 are formed in the order of the conductive layers M21, M22, and M23 from the inside of the surface 1a toward the outer edge. That is, the conductive layer M21 is formed on the element forming region side with respect to the conductive layer M22.

As illustrated in FIG. 5, the conductive layers M01, M02, M03, M04, and M05 in the wiring layer M0 are electrically connected to the conductive layers M11, M12, M13, M14, and M15 in the wiring layer M1 by contact plugs V1, respectively. The conductive layer M11 in the wiring layer M1 is electrically connected to the conductive layer M21 in the wiring layer M2 by a contact plug V2. The conductive layers M12, and M13 in the wiring layer M1 are electrically connected to the conductive layer M22 in the wiring layer M2 by contact plugs V2. The conductive layers M14, and M15 in the wiring layer M1 are electrically connected to the conductive layer M23 in the wiring layer M2 by contact plugs V2.

As described above, the semiconductor chip 1 has the memory cell array region 13 in which the memory cell array 23 is formed between the wiring layers D0, D1, and D2 and the wiring layers M0, M1, and M2. Meanwhile, in the region of the edge seal 3, in a region 13A corresponding to the memory cell array region 13, the memory cell array 23 is not formed, and contact plugs C3 are formed. Similarly, in the region of the edge seal 3, in a region 12A corresponding to the peripheral circuit region 12, peripheral circuits such as transistors are not formed, and the plurality of conductive layers D01 to D04, D11 to D14, and D21 to D24, and the contact plugs C1, and C2 are formed.

In the edge seal 3, the conductive layers M01, M02, M03, and M04 in the wiring layer M0 are electrically connected to the conductive layers D21, D22, D23, and D24 in the wiring layer D2 by the contact plugs C3, respectively.

Therefore, as illustrated in FIG. 5, the conductive layer M21 is electrically connected to the conductive layer D01 by the contact plugs V2, V1, C3, C2, and C1 and the conductive layers M11, M01, D21, and D11. Further, the conductive layer D01 is not electrically connected to the active region AA of the p-type well region WP. The conductive layers M21, M11, M01, D21, and D11 and the contact plugs V2, V1, C3, C2, and C1 connecting the conductive layers make up a stacked body in which the conductive layers and the contact plugs are electrically connected to each other.

As illustrated in FIG. 5, the conductive layer M22 is electrically connected to the conductive layers M12 and M13 by the contact plugs V2. The conductive layer M12 is electrically connected to the active region AA of the p-type well region WP by the contact plugs V1, C3, C2, C1, and CS and the conductive layers M02, D22, D12, and D02. The conductive layer M13 is electrically connected to the active region AA of the p-type well region WP by the contact plugs V1, C3, C2, C1, and CS and the conductive layers M03, D23, D13, and D03. The conductive layers M22, M12, M02, D22, D12, D02, M13, M03, D23, D13, and D03 and the contact plugs V2, V1, C3, C2, C1, and CS connecting the conductive layers make up stacked bodies in which the conductive layers and the contact plugs are electrically connected to each other.

As illustrated in FIG. 5, the conductive layer M23 is electrically connected to the conductive layers M14 and M15 by the contact plugs V2. The conductive layer M14 is electrically connected to the active region AA of the n-type well region WN by the contact plugs V1, C3, C2, C1, and CS and the conductive layers M04, D24, D14, and D04. The conductive layer M15 is electrically connected to the conductive layer M05 by the contact plug V1. Further, the conductive layer M05 is not electrically connected to the active region AA of the non-bias region NB. The conductive layers M23, M14, M04, D24, D14, D04, M15, and M05 and the contact plugs V2, V1, C3, C2, C1, and CS connecting the conductive layers make up stacked bodies in which the conductive layers and the contact plugs are electrically connected to each other.

In FIG. 5, any of the stacked body of the conductive layers M21 to D01, the stacked body of the conductive layers M22 to D02, the stacked body of the conductive layers M22 to D03, the stacked body of the conductive layers M23 to D04, and the stacked body of the conductive layers M23 to M05 has a function as an edge seal.

In the present embodiment, the edge seal 3 has the five stacked bodies described above. The edge seal 3 may only include two or more stacked bodies.

In FIG. 5, lower ends of the contact plugs C3 are connected to the conductive layers D21, D22, D23, and D24 belonging to the wiring layer D2. The present embodiment is not limited thereto. For example, the lower ends of the contact plugs C3 may be connected to a conductive layer located at the same height as the conductor 644, and the corresponding conductive layer may be connected to the conductive layers D21, D22, D23, and D24 belonging to the wiring layer D2 via contact plugs.

### Operation

A power supply voltage VCC is given to the conductive layer M21, and a ground voltage VSS is given to the conductive layers M22 and M23. The conductive layer M22 to which the ground voltage VSS is applied is electrically connected to the p-type well region WP. Meanwhile, the conductive layer M21 to which the power supply voltage VCC is applied is not electrically connected to the p-type well region WP. Therefore, as illustrated in FIG. 5, a capacitance “c” is formed between the two adjacent conductive layers M21 and M22 facing each other in the wiring layer M2. That is, the conductive layer M21 is formed such that a voltage (VCC) different from that of the conductive layer M22 may be supplied. Then, the capacitance “c” is formed between the conductive layer M21 and the conductive layer M22 when the ground voltage VSS as a predetermined voltage is applied to the conductive layer M22.

Likewise, a capacitance “c” is also formed between the conductive layers facing each other in each wiring layer, that is, between the conductive layers M11 and M12, between the conductive layers M01 and M02, between the conductive layers D21 and D22, between the conductive layers D11 and D12, and between the conductive layers D01 and D02. That is, a voltage applied to the stacked body including the conductive layers M21, M11, M01, D21, D11, and D01 is different from that of the stacked body including the conductive layers M22, M12, M02, D22, D12, and D02 to which the ground voltage VSS is applied. As a result, capacitances “c” are formed between the conductive layers M21, M11, M01, D21, D11, and D01 and the conductive layers M22, M12, M02, D22, D12, and D02, respectively.

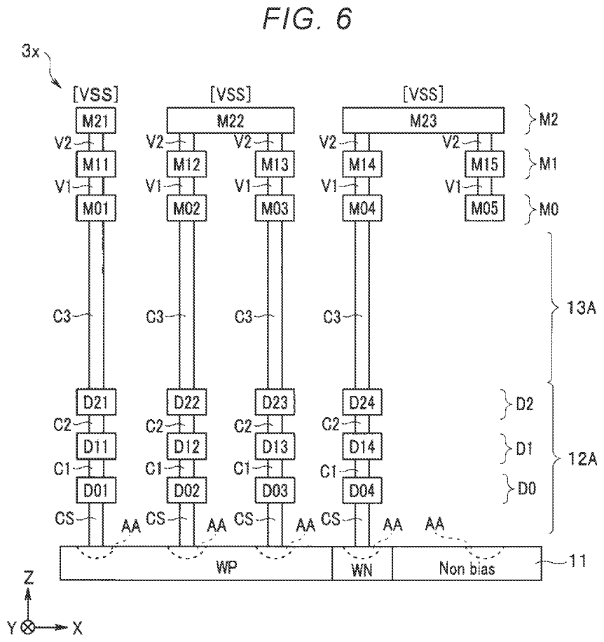

FIG. 6 is a schematic view illustrating a cross section of an edge seal 3x, which is orthogonal to the surface la of the semiconductor chip 1 in a comparative example.

The configuration of the edge seal 3x is substantially the same as that of the edge seal 3 in FIG. 5, but as illustrated in FIG. 6, a ground voltage VSS is given to the conductive layer M21. Further, the conductive layer D01 is electrically connected to the active region AA of the p-type well region WP by the contact plug CS.

Thus, capacitances “c” are not formed between the conductive layers M21, M11, M01, D21, D11, and D01 and the conductive layers M22, M12, M02, D22, D12, and D02, respectively.

Meanwhile, in the edge seal of the embodiment illustrated in FIG. 5, capacitances “c” are generated between the conductive layers M21, M11, M01, D21, D11, and D01 and the conductive layers M22, M12, M02, D22, D12, and D02, respectively. Thus, the edge seal of the embodiment illustrated in FIG. 5 may also fulfill the role as a capacitive element.

Therefore, according to the above-described embodiment, since the role of the capacitive element is added to the edge seal having an existing role, it is possible to provide a semiconductor device whose chip size may be reduced.

Further, in the above-described embodiment, the power supply voltage VCC is applied to one stacked body of the edge seal 3. Instead of the power supply voltage VCC, a power supply voltage VPP or an internal voltage generated in the semiconductor device may be applied.

Further, in the above-described embodiment, the capacitive element using the edge seal 3 may be used as, for example, the inter-power source capacitive element Cap. The capacitive element using the edge seal 3 may be used as a single capacitive element, or may be used in combination with another capacitive element.

According to the above-described embodiment, the capacitive element using the edge seal 3 may be provided only in the vicinity of the plurality of external pads 2 illustrated in FIG. 1. That is, the capacitive element using the edge seal 3 may be provided in at least a part of the outer edge surrounding the element forming region.

Next, modifications will be described.

### Modification 1

In the edge seal 3 of the above-described embodiment, two adjacent conductive layers forming a metal capacitor in each wiring layer have strip shapes extending in parallel to each other. In order to increase the capacitance “c”, each of the two adjacent conductive layers may have a comb shape.

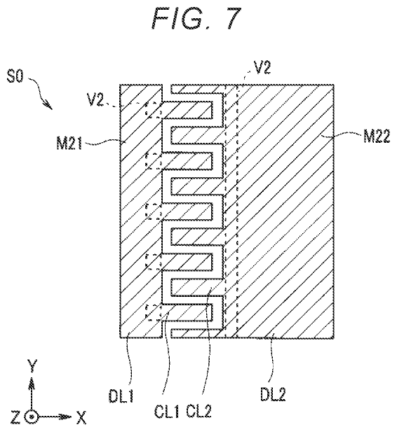

FIG. 7 is a top view illustrating shapes and arrangement of the two adjacent conductive layers M21 and M22 in Modification 1. FIG. 7 illustrates only a part of the edge seal 3.

In FIG. 7, SO indicates shapes and arrangement of the two adjacent conductive layers M21 and M22, which are viewed in a direction orthogonal to the surface la of the semiconductor chip 1. In FIG. 7, the XY directions represent examples of directions.

As indicated by S0, when viewed in the Z direction, each of the two conductive layers M21 and M22 of the wiring layer M2 has a comb shape. Specifically, the shape of the conductive layer M21 has a strip-shaped extension portion DL1 extending along the outer edge (in the Y direction in FIG. 7) of the semiconductor chip 1, and a plurality of protrusion portions CL1 protruding by a predetermined length in a direction (the X direction in FIG. 7) orthogonal to the extension direction of the extension portion DL1. The shape of the conductive layer M22 has a strip-shaped extension portion DL2 extending along the outer edge (in the Y direction in FIG. 7) of the semiconductor chip 1, and a plurality of protrusion portions CL2 extending in a direction (the X direction in FIG. 7) orthogonal to the extension direction of the extension portion DL2. In the shapes of the two conductive layers M21 and M22, in the straight portion DL1 between the two adjacent protrusion portions CL1, a part of one protrusion portion CL2 of the straight portion DL2 is disposed.

That is, the comb shapes of the conductive layer M21 and the conductive layer M22 are formed such that the comb-shaped protrusion portions of the conductive layer M21 are arranged alternately with the comb-shaped protrusion portions of the conductive layer M22 in a direction (the Y direction in FIG. 7) orthogonal to a direction in which the protruding portions protrude.

When the two adjacent conductive layers M21 and M22 have the shapes as illustrated in FIG. 7, opposing areas between two layers increase, and a capacitance between the two adjacent conductive layers M21 and M22 (hereinafter, also referred to as an adjacent capacitance) may be increased.

Further, in the other wiring layers M1, M0, D2, D1, and D0, when shapes of two adjacent conductive layers below the conductive layer M21 and the conductive layer M22 also have the same comb shapes as the conductive layers M21 and M22, the capacitance “c” may be increased due to a further increase in the adjacent capacitance.

Further, the comb shapes described above may not be provided in all the wiring layers M2, M1, M0, D2, D0, and D0. The comb shapes described above may be provided only in a part of the wiring layers M2, M1, M0, D2, D1, and D0.

### Modification 2

In Modification 1 described above, in one or more wiring layers, in order to increase the adjacent capacitance between the two adjacent conductive layers M21 and M22, each of the two adjacent conductive layers has a comb shape. Meanwhile, in Modification 2, in two adjacent wiring layers, a plurality of conductive layers has comb shapes so as to further form a capacitance (hereinafter, also referred to as an inter-layer capacitance) between the two adjacent wiring layers.

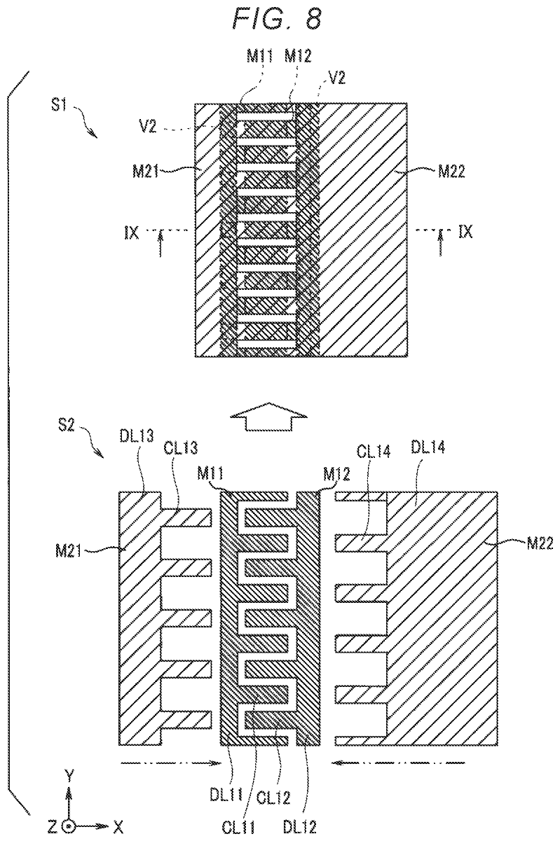

FIG. 8 is a top view illustrating shapes and arrangement of each of the two conductive layers M21 and M22 in the wiring layer M2 and each of the two conductive layers M11 and M12 in the wiring layer M1, in relation to Modification 2. FIG. 8 illustrates only a part of the edge seal 3.

In FIG. 8, S1 indicates the arrangement of the four conductive layers M21, M22, M11, and M12, which are viewed in a direction orthogonal to the surface la of the semiconductor chip 1. Also, in FIG. 8, the XY directions represent examples of directions.

S2 indicates the respective planar shapes of the conductive layers M21, M22, M11, and M12. Each of the conductive layers M21, M22, M11, and M12 has a comb shape. S2 indicates a state where the conductive layers M21 and M22 are shifted in the X direction.

As indicated by S2, each of the two conductive layers M11 and M12 of the wiring layer M1 has a comb shape. Specifically, the shape of the conductive layer M11 has a strip-shaped extension portion DL11 extending along the outer edge of the semiconductor chip 1, and a plurality of protrusion portions CL11 protruding by a predetermined length in a direction orthogonal to the extension direction of the extension portion DL11. The shape of the conductive layer M12 has a strip-shaped extension portion DL12 extending along the outer edge of the semiconductor chip 1, and a plurality of protrusion portions CL12 protruding by a predetermined length in a direction orthogonal to the extension direction of the extension portion DL12. In the shapes of the two conductive layers M11 and M12, in the extension portion DL11 between the two adjacent protrusion portions CL11, a part of one protrusion portion CL12 of the extension portion DL12 is disposed.

Further, as indicated by S2, each of the two conductive layers M21 and M22 of the wiring layer M2 also has a comb shape. Specifically, the shape of the conductive layer M21 has a strip-shaped extension portion DL13 extending along the outer edge of the semiconductor chip 1, and a plurality of protrusion portions CL13 protruding by a predetermined length in a direction orthogonal to the extension direction of the extension portion DL13. The shape of the conductive layer M22 has a strip-shaped extension portion DL14 extending along the outer edge of the semiconductor chip 1, and a plurality of protrusion portions CL14 protruding by a predetermined length in a direction orthogonal to the extension direction of the extension portion DL14.

S1 indicates a state when the two conductive layers M21 and M22 are aligned on the XY plane as indicated by the two-dot chain line arrows in S2. That is, in the shapes of the two conductive layers M21 and M22, in the extension portion DL13 between the two adjacent protrusion portions CL13, a part of one protrusion portion CL14 of the extension portion DL14 is disposed.

The conductive layers M21 and M22 of the wiring layer M2 and the conductive layers M11 and M12 of the wiring layer M1 are formed such that the protrusion portion CL13 and the protrusion portion CL14 partially overlap with the protrusion portion CL12 and the protrusion portion CL11, respectively, when viewed in a direction orthogonal to the surface la. That is, the conductive layer M21 and the conductive layer M12 are formed and arranged such that a capacitance cl is also formed between the conductive layer M21 and the conductive layer M12.

When four conductive layers of two adjacent wiring layers have shapes and arrangement as indicated by S1 of FIG. 8, the inter-power source capacity may be increased by the amount of the adjacent parasitic capacitance of two conductive layers of each wiring layer and the inter-layer capacitance of two wiring layers.

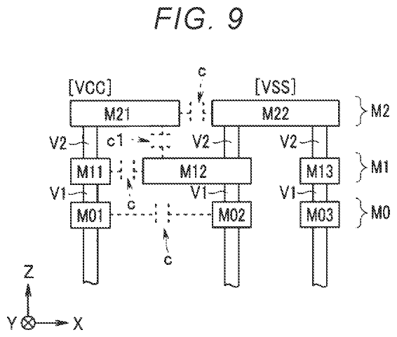

FIG. 9 is a schematic view illustrating the inter-layer capacitance of two wiring layers. FIG. 9 illustrates a cross section taken along the IX-IX line in FIG. 8. As illustrated in FIG. 9, the conductive layer M21 and the conductive layer M12 have regions facing each other in the Z direction. Therefore, the capacitance c1 is formed between the conductive layer M21 of the wiring layer M2, and the conductive layer M12 of the wiring layer M1 different from the wiring layer M2.

Further, in the other wiring layers M1, M0, D2, D1, and D0 as well, each conductive layer may have the shape and arrangement such that an inter-layer capacitance is also formed in addition to an adjacent capacitance.

Further, the comb shapes and inter-layer capacitance forming arrangement as described above may not be provided in all the wiring layers M2, M1, M0, D2, D1, and D0. The comb shapes and inter-layer capacitance forming arrangement as described above may be provided only in a part of the wiring layers M2, M1, M0, D2, D1, and D0.

### Modification 3

In Modification 1 described above, each of the two adjacent conductive layers has a comb shape, whereas in Modification 3, one of the two adjacent conductive layers has an H shape and the other of the two adjacent conductive layers has a cross shape.

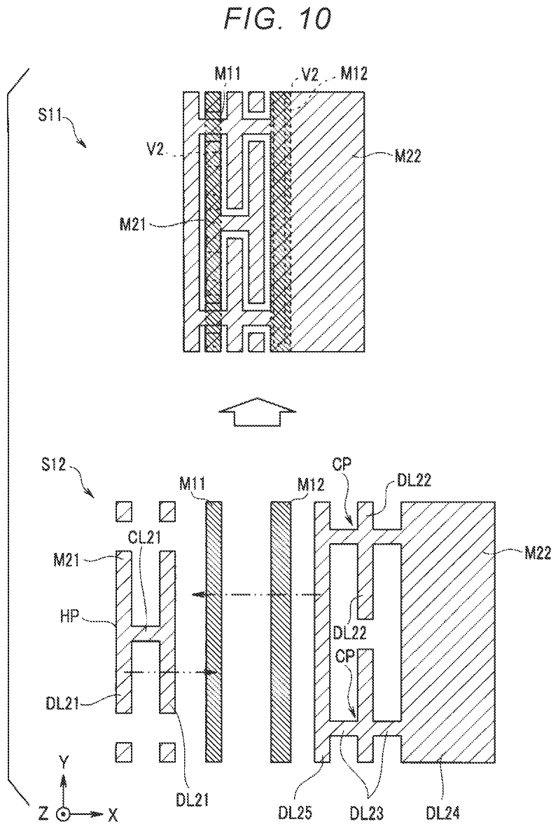

FIG. 10 is a top view illustrating the shape and arrangement of each of the two conductive layers M21 and M22 in the wiring layer M2 in relation to Modification 3. FIG. 10 illustrates only a part of the edge seal 3.

In FIG. 10, S11 indicates the shape and arrangement of each of the two conductive layers M21 and M22, which are viewed in a direction orthogonal to the surface la of the semiconductor chip 1. S12 indicates the respective planar shapes of the conductive layers M21, M22, M11, and M12. Also, in FIG. 10, the XY directions represent examples of directions. S12 indicates a state where the conductive layers M21 and M22 are shifted in the X direction.

As indicated by S11 and S12, the conductive layer M21 of the wiring layer M2 has a plurality of H-shaped portions HP.

Specifically, each H-shaped portion HP has two strip-shaped extension portions DL21 extending along the outer edge of the semiconductor chip 1 (the Y direction in FIG. 10), and a connection portion CL21 connecting central portions of the two extension portions DL21 to each other.

The H-shaped portions HP are arranged at equal intervals along the outer edge of the semiconductor chip 1 (the Y direction in FIG. 10). Each H-shaped portion HP is electrically connected to the conductive layer M11 by the contact plug V2. Therefore, the H-shaped portions HP are electrically connected via the conductive layer M11.

As indicated by S11 and S12, the shape of the conductive layer M22 includes a plurality of cross-shaped portions CP, which surrounds the H-shaped portions HP. Specifically, each cross-shaped portion CP has a strip-shaped extension portion DL22 extending along the outer edge of the semiconductor chip 1 (the Y direction in FIG. 10) and straight portions DL23 extending in both directions (the X direction in FIG. 10) of the extension portion DL22, in the central portion of the extension portion DL22.

The cross-shaped portions CP are arranged at equal intervals along the outer edge of the semiconductor chip 1 (the Y direction in FIG. 10).

Further, the shape of the conductive layer M22 has two strip-shaped extension portions DL24 and DL25 connected to both ends of each straight portion DL23.

S11 indicates a state when the two conductive layers M21 and M22 are aligned on the XY plane as indicated by the two-dot chain line arrows in S12. Therefore, as illustrated in FIG. 10, the shape of the conductive layer M22 is formed such that the conductive layer M22 surrounds each H-shaped portion HP of the conductive layer M21.

The extension portion DL24 is electrically connected to the conductive layer M12 by the contact plug V2. Therefore, the cross-shaped portions CP are electrically connected via the conductive layer M12.

When the two conductive layers M21 and M22 have shapes as illustrated in FIG. 10, it is possible to increase the adjacent capacitance of the two conductive layers M21 and M22.

Further, in the other wiring layers M1, M0, D2, D1, and D0, when shapes of two adjacent conductive layers also have the same shapes as the conductive layers M21 and M22, the inter-power source capacity may be increased due to a further increase in the adjacent capacitance.

Further, the shape including a cross shape as described above may not be provided in all the wiring layers M2, M1, M0, D2, D1, and D0. The shape including a cross shape described above may be provided only in a part of the wiring layers M2, M1, M0, D2, D1, and D0.

### Modification 4

In Modification 3 described above, in order to increase the capacitance, in each of one or more wiring layers, one of two adjacent conductive layers has a shape including a cross shape, and the other has a shape surrounding the cross shape. Meanwhile, in addition to a first wiring layer having the shape of Modification 3, the edge seal of Modification 4 further has a second wiring layer that constitutes an inter-layer capacitance between the second wiring layer and the first wiring layer. The second wiring layer is a wiring layer adjacent to the first wiring layer.

In the following example, the first wiring layer is the wiring layer M2, and the second wiring layer is the wiring layer M1.

In the wiring layer M2, one conductive layer M21 of two adjacent conductive layers has an H-shaped portion, and the other conductive layer M22 of the two adjacent conductive layers has a cross-shaped portion. In the second wiring layer M1, one (M11) of two adjacent conductive layers has a cross-shaped portion, and the other (M12) of the two adjacent conductive layers also has a cross-shaped portion.

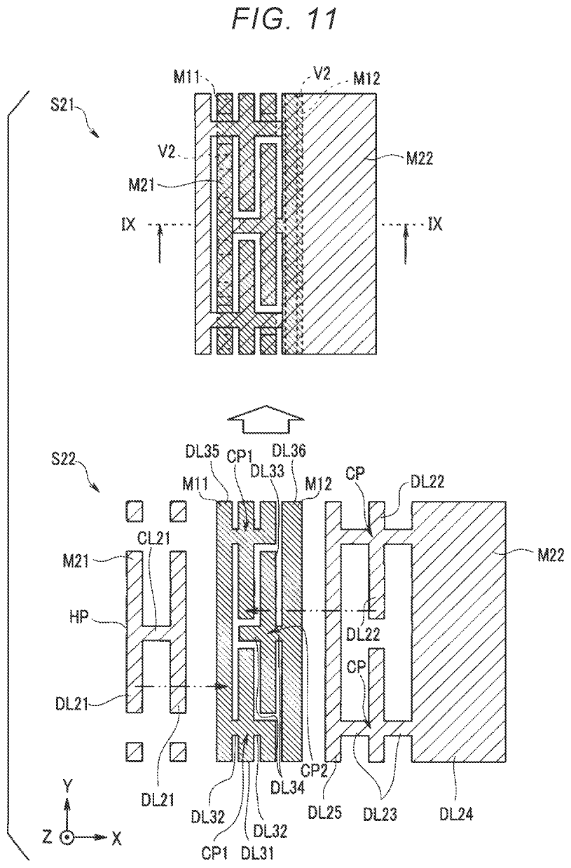

FIG. 11 is a top view illustrating shapes and arrangement of the two conductive layers M21 and M22 in the wiring layer M2 and the two conductive layers M11 and M12 in the wiring layer M1, in relation to Modification 4. FIG. 11 illustrates only a part of the edge seal 3.

In FIG. 11, S21 indicates the arrangement of the four conductive layers M21, M22, M11, and M12, which are viewed in a direction orthogonal to the surface la of the semiconductor chip 1.

S22 indicates the respective planar shapes of the conductive layers M21, M22, M11, and M12. Further, in FIG. 11, the XY directions indicate examples of directions. S22 indicates a state where the conductive layers M21 and M22 are shifted in the X direction. The conductive layer M21 has an H-shaped portion HP. The conductive layer M22 has two extension portions DL24 and DL25 connected to both ends of each straight portion DL23. The conductive layer M22 has a cross-shaped portion CP between the two extension portions DL24 and DL25.

The conductive layers M11 and M12 also have cross-shaped portions CP1 and CP2. As indicated by the two-dot chain line arrows, when the two conductive layers M21 and M22 are aligned on the XY plane, the four conductive layers M21, M22, M11, and M12 are arranged as indicated by S21.

Specifically, the cross-shaped portion CP1 of the conductive layer M11 has a strip-shaped extension portion DL31 extending along the outer edge of the semiconductor chip 1 (the Y direction in FIG. 11), and straight portions DL32 extending in both directions (the X direction in FIG. 11) of the extension portion DL31, in the central portion of the extension portion DL31. The cross-shaped portion CP2 of the conductive layer M12 has an extension portion DL33 extending along the outer edge of the semiconductor chip 1 (the Y direction in FIG. 11), and straight portions DL34 extending in a direction orthogonal to the extension direction of the extension portion DL33 (the X direction in FIG. 11). The two conductive layers M11 and M12 are arranged such that a part of the straight portion DL34 of the cross-shaped portion CP2 of the conductive layer M12 is located between the two extension portions DL31 of the two adjacent cross-shaped portions CP1 of the conductive layer M11.

The shape of the conductive layer M11 further has an extension portion DL35 connected to one side of each straight portion DL32. The shape of the conductive layer M12 has an extension portion DL36 connected to one side of each straight portion DL34. As illustrated in FIG. 11, each cross-shaped portion CP2 of the conductive layer M12 and each cross-shaped portion CP1 of the conductive layer M11 are arranged between the two extension portions DL35 and DL36.

S21 indicates a state when the two conductive layers M21 and M22 are aligned on the XY plane as indicated by the two-dot chain line arrows in S22. That is, the shape of the conductive layer M22 is formed such that the conductive layer M22 surrounds each H-shaped portion HP.

When four conductive layers of two adjacent wiring layers have shapes and arrangement as illustrated in FIG. 10, it is possible to increase the adjacent capacitance of two conductive layers of each wiring layer and the inter-layer capacitance of two wiring layers.

The inter-layer capacitance cl between the conductive layers M21 and M12 is formed as illustrated in FIG. 9. FIG. 9 illustrates a cross section taken along the IX-IX line in FIG. 11.

Further, in other wiring layers M1, M0, D2, D1, and D0 as well, each conductive layer may have the shape and arrangement so as to form not only an adjacent capacitance but also an inter-layer capacitance.

In all adjacent two wiring layers M2, M1, M0, D2, D1, and D0, an inter-layer capacitance may not be formed by the shape including a cross shape as described above. Only in a part of adjacent two wiring layers M2, M1, M0, D2, D1, and D0, arrangement for forming an inter-layer capacitance by the shape including a cross shape as described above may be made.

### Modification 5

The semiconductor device of the above-described embodiment is a NAND-type flash memory, and as illustrated in FIG. 5, has a configuration where the peripheral circuit region 12, and the memory cell array region 13 are formed in this order on the semiconductor substrate 11, and the plurality of wiring layers M0, M1, and M2 is formed in the uppermost layer. Alternatively, the above-described adjacent capacitance may be formed in a semiconductor device in which an array chip having the memory cell array region 13 and a circuit chip having the peripheral circuit region 12 are bonded to each other.

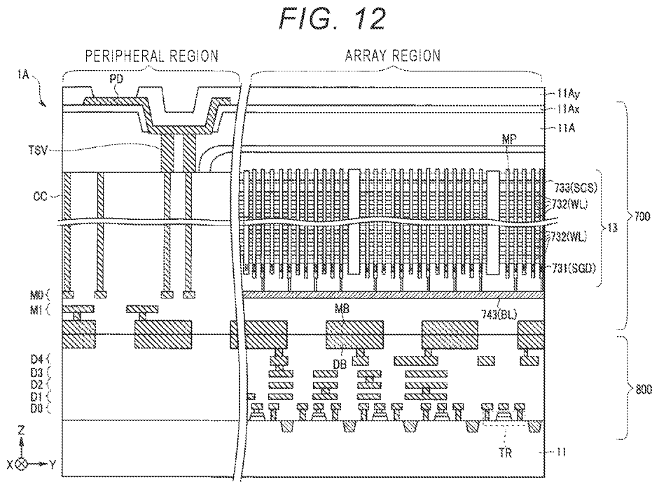

FIG. 12 is a schematic cross-sectional view illustrating the configuration of a semiconductor chip 1A of the present modification 5. As illustrated in FIG. 12, the semiconductor device has a configuration where an array chip 700 and a circuit chip 800 are bonded to each other. In the array chip 700, the memory cell array 23, and various wirings for connecting the memory cell array 23 to the circuit chip 800 are formed. The array chip 700 includes an array region and a peripheral region, and the memory cell array 23 is formed in the array region. A wiring layer 733 as a select gate line SGS and wiring layers 732 as word lines WL are formed into flat plate shapes parallel to the surface of a semiconductor substrate 71. Wiring layers 731 as select gate lines SGD extend in a direction (the X direction) orthogonal to the Y direction in which a wiring layer 743 as a bit line BL extends, and are arranged at predetermined intervals in the Y direction. Each wiring layer 731 is formed through a memory pillar MP above the wiring layers 732. The wiring layer 743 is electrically connected to any of bonding electrodes MB via a contact plug or another wiring layer. The bonding electrodes MB are used for connection with the circuit chip 800.

A plurality of electrode pads PD is provided on the upper surface of the array chip 700 in the Z direction. The electrode pads PD are formed in the MA wiring layer. The electrode pad PD is used for connecting the semiconductor chip 1A to external devices. The electrode pad PD is electrically connected to any of the conductive layers of the wiring layer M0 via a through via TSV and a contact plug CC. An insulating film 11Ax is formed on the upper surface of the array chip 700 in the Z direction, and a passivation film 11Ay is formed on the insulating film 11Ax. An opening corresponding to the electrode pad PD is formed in the passivation film 11Ay.

In the circuit chip 800, the logic control circuit 21, the sense amplifier 24, the row decoder 25, the register 26, the sequencer 27, the voltage generation circuit 28, etc., are formed. Gate electrodes, sources, and drains of a plurality of transistors TR formed on the semiconductor substrate 11 are electrically connected to any of bonding electrodes DB via contact plugs or a plurality of wiring layers. The bonding electrode DB is electrically connected to the opposed bonding electrode MB.

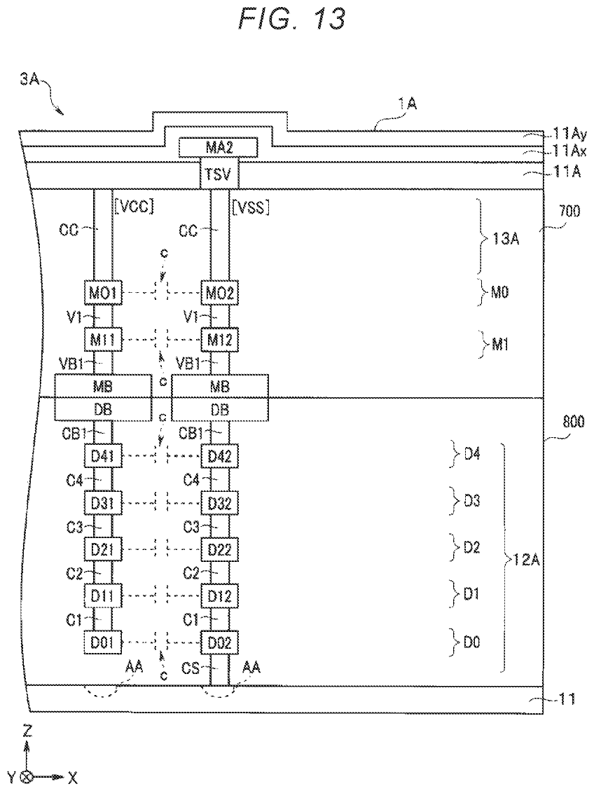

FIG. 13 is a schematic view of a NAND-type flash memory having two semiconductor chips bonded to each other. FIG. 13 illustrates a cross section of a part of a portion of an edge seal 3A. In particular, FIG. 13 illustrates a partial cross section of the edge seal 3A. FIG. 13 illustrates two stacked bodies in the edge seal 3A.

The semiconductor chip 1A of Modification 5 is formed by bonding the circuit chip 800 to the array chip 700.

The circuit chip 800 has the peripheral circuit region 12. A region 12A of the edge seal 3A corresponding to the peripheral circuit region 12 has a plurality of wiring layers D0 to D4 formed on the semiconductor substrate 11. The wiring layer D0 includes conductive layers D01, D02, etc. The wiring layer D1 includes conductive layers D11, D12, etc. The wiring layer D2 includes conductive layers D21, D22, etc. The wiring layer D3 includes conductive layers D31, D32, etc. The wiring layer D4 includes conductive layers D41, D42, etc. Further, the circuit chip 800 has the plurality of bonding electrodes DB for bonding with the array chip 700. The plurality of bonding electrodes DB is provided on the surface of the circuit chip 800 to be bonded to the array chip 700.

The conductive layer D01 is electrically connected to the conductive layer D11, the conductive layer D21, the conductive layer D31, the conductive layer D41, and the bonding electrode DB by contact plugs C1, C2, C3, C4 and CB1 connecting these to each other.

The conductive layer D02 is electrically connected to the conductive layer D12, the conductive layer D22, the conductive layer D32, the conductive layer D42, and the bonding electrode DB by contact plugs C1, C2, C3, C4 and CB1 connecting these to each other.

FIG. 13 illustrates only five wiring layers D0 to D4 in the circuit chip 800. The number of wiring layers may be less than or equal to or larger than five.

The array chip 700 has the memory cell array region 13. The array chip 700 has the memory cell array region 13 on a semiconductor substrate 11A, a region 13A of the edge seal 3A corresponding to the memory cell array region 13, and wiring layers M0 and M1. The insulating film 11Ax is formed on the lower surface of the semiconductor substrate 11A (the upper surface in FIG. 13). Further, the passivation film 11Ay is formed on the insulating film 11Ax. The wiring layer M0 includes conductive layers M01, M02, etc. The wiring layer M1 includes conductive layers M11, M12, etc. Further, the array chip 700 has the plurality of bonding electrodes MB for bonding with the circuit chip 800. The plurality of bonding electrodes MB is provided on the surface of the array chip 700 to be bonded to the circuit chip 800.

The conductive layer M01 is electrically connected to the conductive layer M11 and the bonding electrode MB by contact plugs V1 and VB1. Further, the conductive layer M01 is electrically connected to the semiconductor substrate 11A by the contact plug CC. The conductive layer M02 is electrically connected to the conductive layer M12 and the bonding electrode MB by the contact plugs V1 and VB1. Further, the conductive layer M02 is electrically connected to a conductive layer MA2 by the contact plug CC and the through via TSV.

The conductive layer MA2 is formed in the insulating film 11Ax, and the through via TSV is connected to the contact plug CC by penetrating the semiconductor substrate 11A.

Further, in FIG. 13, the array chip 700 is illustrated as having only two wiring layers M0 and M1, but may have one wiring layer, or three or more wiring layers.

Therefore, the conductive layers M01, M11, MB, DB, D41, D31, D21, D11, and D01 and the contact plugs V1, VB1, CB1, C4, C3, C2, C1, and CC make up a stacked body in which the conductive layers and the contact plugs are electrically connected to each other. Likewise, the conductive layers MA2, M02, M12, MB, DB, D42, D32, D22, D12, and D02 and the contact plugs V1, VB1, CB1, C4, C3, C2, C1, CS, CC, and TSV make up a stacked body in which the conductive layers and the contact plugs are electrically connected to each other.

As illustrated in FIG. 13, in the present semiconductor chip LA, a power supply voltage VCC is applied to the conductive layer M01. The conductive layer D01 to which the power supply voltage VCC is applied is not electrically connected to the active region AA of the semiconductor substrate 11.

A ground voltage VSS is applied to the conductive layer M02 adjacent to the conductive layer M01 via the conductive layer MA2, the through via TSV, and the contact plug CC. The conductive layer D02 to which the ground voltage VSS is applied is electrically connected to the active region AA of the semiconductor substrate 11 by the contact plug CS.

In FIG. 13, the contact plug CC connected to the conductive layer M01 is connected to the semiconductor substrate 11A. The contact plug CC may be connected to a conductive layer MA1 (not illustrated) via TSV. In this case, an adjacent capacitance is also formed between MA1 and MA2.

Further, in the semiconductor chip LA in which the array chip 700 having the memory cell array region 13 and the circuit chip 800 having the peripheral circuit region 12 are bonded to each other, the semiconductor substrate 11A of the array chip 700 having the memory cell array region 13 may not be provided.

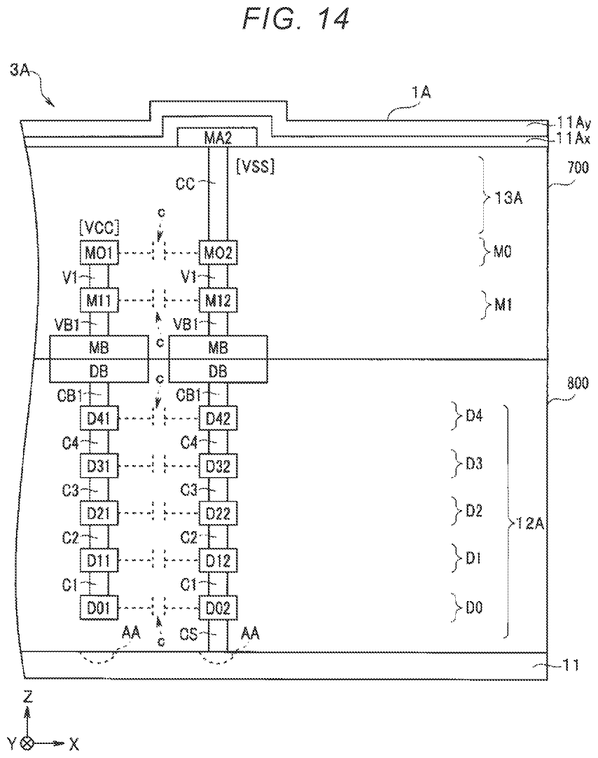

FIG. 14 is a schematic view of another example of the NAND-type flash memory having two semiconductor chips bonded to each other. The semiconductor chip 1A illustrated in FIG. 14 is a semiconductor chip in which the semiconductor substrate 11A in FIG. 13 is removed by using, for example, a chemical mechanical polishing (CMP) method. The conductive layer MA2 in the insulating film 11Ax is electrically connected to the conductive layer M02 via the contact plug CC. In the case of FIG. 14, a power supply voltage VCC is applied to the conductive layer M01, and a ground voltage VSS is applied to the conductive layer M02.

Therefore, in the semiconductor chip 1A as well, an adjacent capacitance is formed between two adjacent conductive layers as in the above-described embodiment.

Further, in FIG. 14, the contact plug CC connected to the conductive layer M01 is not formed. The conductive layer M01 may be connected to the conductive layer MA1 (not illustrated) via the contact plug CC. In this case, an adjacent capacitance is also formed between MA1 and MA2.

In the semiconductor chip 1A as well, shapes and arrangement of conductive layers in all wiring layers or a part of the wiring layers may have shapes and arrangement as described in Modifications 1 to 4.

### Modification 6

The above-described embodiment and each modification are examples of a NAND-type flash memory as the semiconductor device.

The edge seal in the embodiment and Modifications 1 to 5 described above is also applicable to a semiconductor chip such as a DRAM which is a volatile memory.

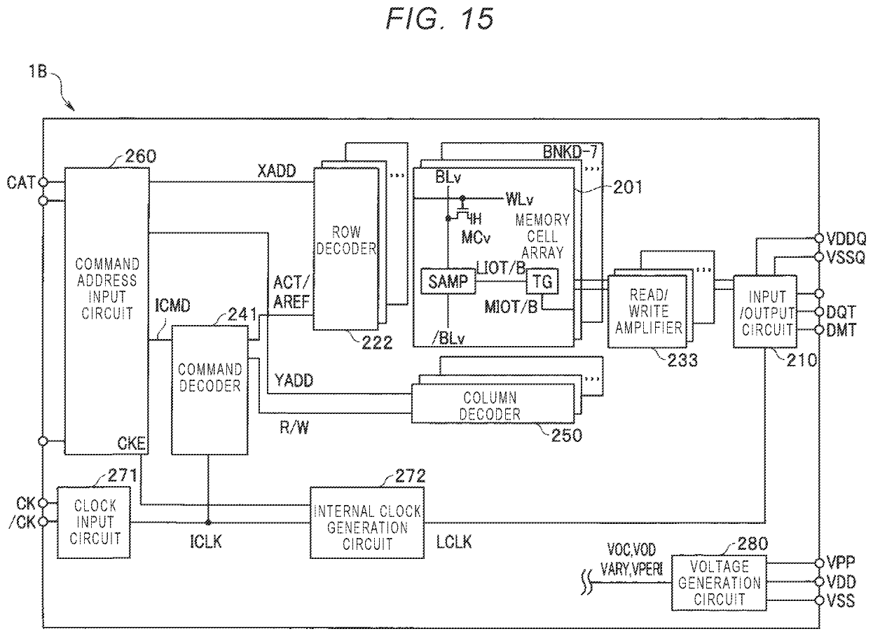

FIG. 15 is a block diagram of a semiconductor device of Modification 6. As illustrated in FIG. 15, a semiconductor chip 1B of Modification 6 includes a memory cell array 201, peripheral circuits such as an input/output circuit 210, a row decoder 222, a read/write amplifier 233, a command decoder 241, a column decoder 250, a command address input circuit 260, a clock input circuit 271, an internal clock generation circuit 272, and a voltage generation circuit 280, and a plurality of external terminals such as clock terminals CK and CK/, a command/address terminal CAT, a data terminal DQT, a data mask terminal DMT, and power terminals VPP, VDD, VSS, VDDQ, and VSSQ.

The memory cell array 201 includes a plurality of banks BNK0 to BNK7. Each of the banks BNK0 to BNK7 has a plurality of word lines WLv and a plurality of bit lines BLv and /BLv, and a memory cell MCv is disposed at each of the intersections between the word lines WLv and the bit lines BLv. The memory cell MCv is configured as, for example, a transistor, and stores volatile data. Therefore, refreshing is periodically performed so as to maintain data stored in the memory cell array 201. In FIG. 15, for the convenience of descriptions, a refresh circuit, etc., provided in the DRAM are omitted.

By providing these memory cells MCv, the semiconductor device of the present modification is configured as a dynamic random access memory (DRAM).

A sense amplifier circuit SAMP includes a transfer gate, and is disposed corresponding to the bit lines BLv and /BLv. Also, the sense amplifier circuit SAMP is connected to local input/output lines LIOT and LIOB via a column switch (not illustrated) and also is connected to main input/output lines MIOT and MIOB via the transfer gate TG. The transfer gate TG functions as a switch. The sense amplifier circuit SAMP senses data read from the memory cell MCv, similarly to the sense amplifier circuit of a column decoder (FIG. 2) of the above-described embodiment.

Memory addresses are associated with the memory cells MCv in the memory cell array 201, respectively. Among the external terminals, the command/address terminal CAT receives a memory address from an external device such as, for example, a memory controller. The memory address received by the command/address terminal CAT is transferred to the command address input circuit 260. When the memory address is received, the command address input circuit 260 transmits a decoded row address XADD to the row decoder 222, and transmits a decoded column address YADD to the column decoder 250.

Further, the command/address terminal CAT receives a command from, for example, the memory controller or the like. The command received by the command/address terminal CAT is transmitted as an internal command signal ICMD, to the command decoder 241 through the command address input circuit 260.

The command decoder 241 includes a circuit that decodes the internal command ICMD and generates a signal for executing an internal command. The command decoder 241 transmits, for example, an activated command ACT and a refresh command AREF to the row decoder 222. The row decoder 222 is connected to the word line WLv, and selects the word line WLv according to the command ACT and the refresh command AREF received from the command decoder 241.

The command decoder 241 transmits, for example, a read/write command R/W to the column decoder 250. The column decoder 250 is connected to the bit line BLv, and selects the bit line BLv according to the read/write command R/W received from the command decoder 241.

When data is read, the command/address terminal CAT receives a memory address together with a read command. Accordingly, data is read from the memory cell MCv in the memory cell array 201 specified by the memory address. The read data is output from the data terminal DQT to the outside via the read/write amplifier 233 and the input/output circuit 210.

When data is written, the command/address terminal CAT receives a memory address together with a write command, and the data terminal DQT receives write data. If necessary, a data mask is transmitted to the data mask terminal DMT. The write data is transmitted to the memory cell array 201 via the input/output circuit 210 and the read/write amplifier 233. Accordingly, the write data is written into the memory cell MCv specified by the memory address.

The read/write amplifier 233 includes various latch circuits that temporarily store read data and write data. A configuration corresponding to the column decoder 140 (FIG. 2) of the above described embodiment is formed by the read/write amplifier 233 and the sense amplifier circuit SAMP.

Power supply voltages VPP, VDD, and VSS are supplied to the power terminals VPP, VDD, and VSS, respectively, and the power supply voltages VPP, VDD, and VSS are further supplied to the voltage generation circuit 280. The voltage generation circuit 280 generates various internal voltages VOC, VOD, VARY, and VPERI based on the power supply voltages VPP, and VDD. The internal voltage VOC is mainly used in the row decoder 222, the internal voltages VOD, and VARY are mainly used in the sense amplifier circuit SAMP of the memory cell array 201, and the internal voltage VPERI is used in other peripheral circuit blocks.

Power supply voltages VDD and VSS are also supplied to the power terminals VDDQ and VSSQ, and the power supply voltages VDD and VSS are further supplied to the input/output circuit 210. Dedicated power supply voltages are applied to the power terminals VDDQ and VSSQ so that a power supply noise generated in the input/output circuit 210 is not propagated to other circuit blocks. The power supply voltages VDD and VSS supplied to the power terminals VDDQ and VSSQ may be the same voltages as the power supply voltages VDD and VSS supplied to the power terminals VDD and VSS.

Complementary external clock signals are input to the clock terminals CK and /CK. The external clock signal is supplied to the clock input circuit 271. The clock input circuit 271 generates an internal clock signal ICLK. The internal clock signal ICLK is supplied to the internal clock generation circuit 272 and the command decoder 241.

The internal clock generation circuit 272 generates various internal clock signals LCLK when enabled by a clock enable CKE from the command address input circuit 260. The internal clock signals LCLK are used to measure the timings of various internal operations. For example, the internal clock signals LCLK are output to the input/output circuit 210. The input/output circuit 210 transmits and receives data on the data terminal DQT by performing operations based on the input internal clock signals LCLK.

Even in such a semiconductor chip of a DRAM, the edge seal described in the embodiment and Modifications 1 to 5 is applicable.

According to the above-described embodiment and each modification, it is possible to provide a semiconductor device whose chip size may be reduced.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
an active region; and
an edge seal formed on at least a portion of an outer edge of the active region,
wherein the edge seal includes a first stacked body having a first conductive layer, and a second stacked body having a second conductive layer,
wherein the first conductive layer is coupled to a first voltage, the second conductive layer is coupled to a second voltage different from the first voltage, and the first conductive layer faces the second conductive layer.

2. The semiconductor device according to claim 1, wherein the first conductive layer is formed closer to the active region than the second conductive layer is, and the first voltage is higher than the second voltage.

3. The semiconductor device according to claim 1, wherein the first voltage is a power supply voltage VCC, and the second voltage is a power supply voltage VSS.

4. The semiconductor device according to claim 1, wherein the first voltage is a power supply voltage VPP, and the second voltage is a power supply voltage VSS.

5. The semiconductor device according to claim 1, wherein the first stacked body has a third conductive layer electrically connected to the first conductive layer, the second stacked body has a fourth conductive layer electrically connected to the second conductive layer, and the third conductive layer faces the fourth conductive layer.

6. The semiconductor device according to claim 1, wherein when viewed from the top, each of the first conductive layer and the second conductive layer has an extension portion extending in a first lateral direction, and protrusion portions protruding with a length in a second lateral direction orthogonal to the first lateral direction and arranged with intervals along the first direction, and
the protrusion portions of the first conductive layer are arranged alternately with the protrusion portions of the second conductive layer.

7. The semiconductor device according to claim 1, wherein one of the first conductive layer or the second conductive layer has an H shape when viewed from the top, and the other of the first conductive layer or the second conductive layer has a shape surrounding the H shape when viewed from the top.

8. The semiconductor device according to claim 1, wherein the first conductive layer is provided in a first wiring layer,
the second stacked body has a third conductive layer,
the third conductive layer is provided in a second wiring layer adjacent to the first wiring layer, and is electrically connected to the second conductive layer, and
the first conductive layer faces the third conductive layer.

9. The semiconductor device according to claim 1, wherein the semiconductor device is a semiconductor memory device having a non-volatile memory.

10. The semiconductor device according to claim 1, wherein the semiconductor device is a semiconductor memory device having a volatile memory.

11. The semiconductor device according to claim 1, wherein the first conductive layer and the second conductive layer form, at least in part, a capacitance.

12. The semiconductor device according to claim 1, where each of the first conductive layer and the second conductive layer has a respective plurality of protrusion portions extending along a first lateral direction, and wherein at least one of the protrusion portions of the first conductive layer is interposed between neighboring ones of the protrusion portions of the second conductive layer along a second lateral direction perpendicular to the first lateral direction.

13. A semiconductor device comprising:
a region having a memory cell array; and
an edge seal surrounding the region,
wherein the edge seal includes a first stacked body having a first conductive layer, and a second stacked body having a second conductive layer,
wherein the first conductive layer is coupled to a first voltage, the second conductive layer is coupled to a second voltage different from the first voltage, and the first conductive layer is disposed adjacent the second conductive layer thereby forming, at least in part, a capacitance.

14. The semiconductor device according to claim 13, wherein the first voltage is a power supply voltage VCC, and the second voltage is a power supply voltage VSS.

15. The semiconductor device according to claim 13, wherein the first voltage is a power supply voltage VPP, and the second voltage is a power supply voltage VSS.

16. The semiconductor device according to claim 13, wherein the memory cell array is a non-volatile memory array.

17. The semiconductor device according to claim 13, wherein the memory cell array is a volatile memory array.

18. The semiconductor device according to claim 13, where each of the first conductive layer and the second conductive layer has a respective plurality of protrusion portions extending along a first lateral direction, and wherein at least one of the protrusion portions of the first conductive layer is interposed between neighboring ones of the protrusion portions of the second conductive layer along a second lateral direction perpendicular to the first lateral direction.

19. The semiconductor device according to claim 13, wherein the first stacked body has a first bonding electrode in a first chip and a second bonding electrode in a second chip, and the first chip has the memory cell array.

20. The semiconductor device according to claim 13, further comprising:
a plurality of electrode pads formed in a top wiring layer;
wherein the second stacked body has a conductive layer electrically connected to the first conductive layer, and the conductive layer is formed in the top wiring layer.
